(19) United States
(12) Patent Application Publication
(10) Pub. No.: US 2012/0018768 A1
(43) Pub. Date: Jan. 26, 2012

(54) LED-BASED LIGHT EMITTING DEVICES

(75) Inventors: Yi-Qun Li, Danville, CA (US); Charles Owen Edwards, Pleasanton, CA (US); Chih-Wei Huang, Linyuan Township (TW); Ah Liu, ChuPei City (TW)

(73) Assignee: INTEMATIX CORPORATION, Fremont, CA (US)

(21) Appl. No.: 13/188,187

(22) Filed: Jul. 21, 2011

Related U.S. Application Data
(60) Provisional application No. 61/367,784, filed on Jul. 26, 2010.

(51) Int. Cl. H01L 33/62

(52) U.S. Cl. 257/99; 257/E33.066

(57) ABSTRACT

An LED-based light emitting device comprises: a substrate; at least one LED die mounted to the substrate; at least one bond wire that electrically connects the LED die; and a light transmissive material (silicone) encapsulating the at least one LED die and at least one bond wire. The at least one bond wire has a hook-shaped portion that loops back on itself.

### CROSS REFERENCE TO RELATED APPLICATION

This application claims the benefit of priority to U.S. Provisional Patent Application No. 61/367,784, filed Jul. 26, 2010, entitled “LED-Based Light Emitting Devices”, by Yi-Qun Li, et al., the specification and drawings of which are incorporated herein by reference.

### BACKGROUND OF THE INVENTION

1. Field of the Invention

This invention relates to LED-based (Light Emitting Diode-based) light emitting devices and in particular LED wire bonding.

2. Description of the Related Art

Due to their long operating life expectancy (>50,000 hours) and high luminous efficacy (70 lumens per watt and higher) high brightness “white LEDs” are increasingly being used to replace conventional fluorescent, compact fluorescent and incandescent light sources. White light emitting LEDs (“white LEDs”) are a relatively recent innovation and it was not until LEDs emitting in the blue/ultraviolet part of the electromagnetic spectrum were developed that it became practical to develop white light sources based on LEDs. As taught, for example in U.S. Pat. No. 5,998,925, white LEDs include one or more phosphor materials, that is photo-luminescent materials, which absorb a portion of the radiation emitted by the LED and re-emit radiation of a different color (wavelength). Typically, the LED chip generates blue light and the phosphor material(s) absorbs a percentage of the blue light and re-emits yellow light or a combination of green and red light, green and yellow light or yellow and red light. The portion of the blue light generated by the LED that is not absorbed by the phosphor material combined with the light emitted by the phosphor material provides light which appears to the human eye as being nearly white in color.

An example of a white light emitting device based on LEDs is described in co-pending U.S. Patent Publication No. US 2009/0294780 (Published Dec. 3, 2009) and is shown in FIG. 1. Referring to FIG. 1 the device 10 comprises a ceramic package 12, such as a low temperature co-fired ceramic (LTCC), having an array of nine circular recesses (cavities) 14 (FIG. 1 shows an array of nine recesses arranged in a square array 3 rows by 3 columns) in which each recess 14 is configured to house a respective LED die (chip) 16, typically a blue light emitting gallium nitride (GaN) based LED die. The walls of the recesses 14 are inclined and can include a reflective surface such as a metallization layer of silver or aluminum such that each recess 14 comprises a reflector cup for increasing emission of light from the device. The package 12 is a multi-layered structure and incorporates a pattern of electrically conducting tracks 18 configured to interconnect the LED dies 16 in a desired configuration. The conducting tracks 18 are configured such that a part of them extends into the recess to provide a pair of electrode pads 20 on the floor of the recess 14 for electrical connection to a respective LED die 16. On a lower face of the package 12 one or more solder pads 22 are provided for electrically connecting the device 10 to a power source. The solder pads 22 are connected to the conducting tracks 18 by conducting vias 24. Each LED die 16 is mounted in thermal communication with a mounting pad 26 on the floor of the recess by soldering or using a thermally conducting adhesive. Anode and cathode electrodes 28 on the LED die 16 are connected by a bond wire 30 to a respective electrode pad 20 on the floor of the recess. Each recess 14 is filled (potted) with a light transmissive polymer material 32, typically a silicone, which is loaded with the powdered phosphor material(s) (not shown). Often, as shown in FIG. 1, each recess is over filled such that the light transmissive material forms a dome-shaped (generally hemispherical) encapsulation.

The inventors have discovered that a problem with existing LED-based light emitting devices is that the bond wire can fail during thermal cycling of the device. The present invention arose in an endeavor to at least in part mitigate the problems with the existing devices.

### SUMMARY OF THE INVENTION

Embodiments of the invention are directed to LED-based light emitting devices in which the bond wire(s) used to connect the LED dies include a hook-shaped end portion such that the bond wire loops back on itself. The hook-shaped portion reduces failure of the bond wire due to fatigue that can arise from differences in the coefficient of thermal expansion of the bond wire and the light transmissive material in which the bond wire and LED die are typically encapsulated.

According to the invention a light emitting device comprises: a substrate; at least one LED die mounted to the substrate; at least one bond wire that electrically connects the LED die; and a light transmissive material encapsulating the at least one LED die and at least one bond wire; wherein the at least one bond wire has a hook-shaped portion that loops back on itself.

Preferably the hook-shaped portion extends above the LED die by a distance of at least 0.2 mm.

The hook-shaped portion can be substantially semicircular in form and preferably has a radius of at least 0.1 mm. The bond wire can have a shape that resembles a “candy cane”.

The substrate can comprise a package having a cavity in which the at least one LED die is mounted. Alternatively the LED die(s) can be mounted on the face of a substantially planar substrate such as a metal core printed circuit board.

According to a further aspect of the invention a light emitting device comprises at least one LED die that is electrically connected by a bond wire having a hook-shaped portion that loops back on itself.

### BRIEF DESCRIPTION OF THE DRAWINGS

In order that the present invention is better understood LED bond wires and LED-based light emitting devices in accordance with the invention will now be described, by way of example only, with reference to the accompanying drawings in which:

FIG. 1 is a sectional view of a known white LED as previously described;

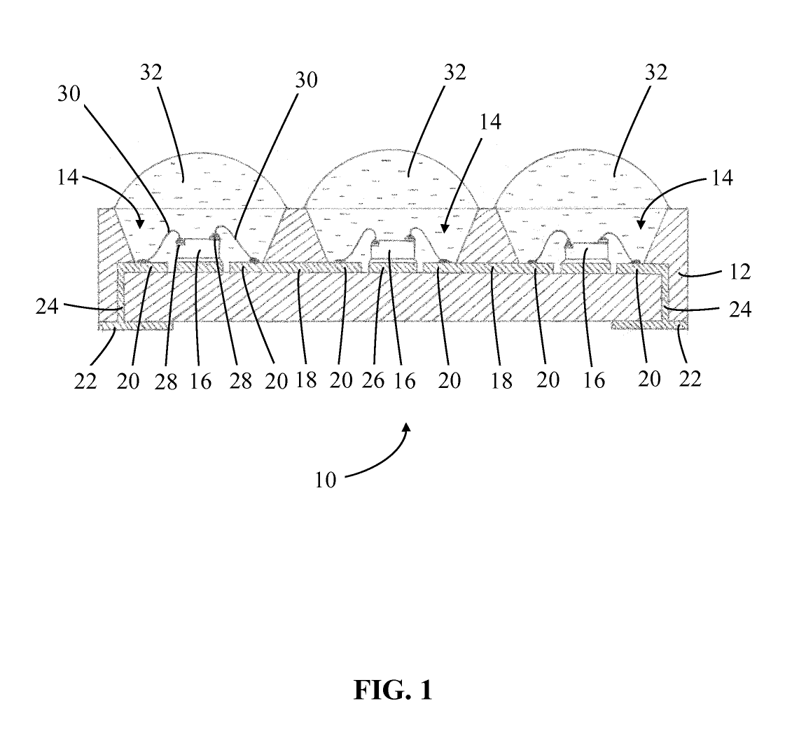

FIG. 2 is a schematic representation of a known LED bond wire;

FIG. 3 is a schematic representation of a further known LED bond wire

FIG. 4 is a schematic representation of an LED bond wire in accordance with an embodiment of the invention;

FIG. 5 is a sectional view of an LED-based light emitting device in accordance with the invention; and

FIG. 6 is a sectional view of an LED-based light emitting device in accordance with another embodiment of the invention.

### DETAILED DESCRIPTION OF THE INVENTION

Embodiments of the invention are directed to LED-based light emitting devices in which the bond wires used to electrically connect the LED dies include a hook-shaped end portion such that the bond wire loops back on itself before connecting to the LED die. It has been found that the hook-shaped portion reduces failure of the bond wire due to fatigue that can arise from differences in the coefficient of thermal expansion of the bond wire and the light transmissive material in which the bond wire and LED die are typically encapsulated.

Throughout this patent specification like reference numerals are used to denote like parts.

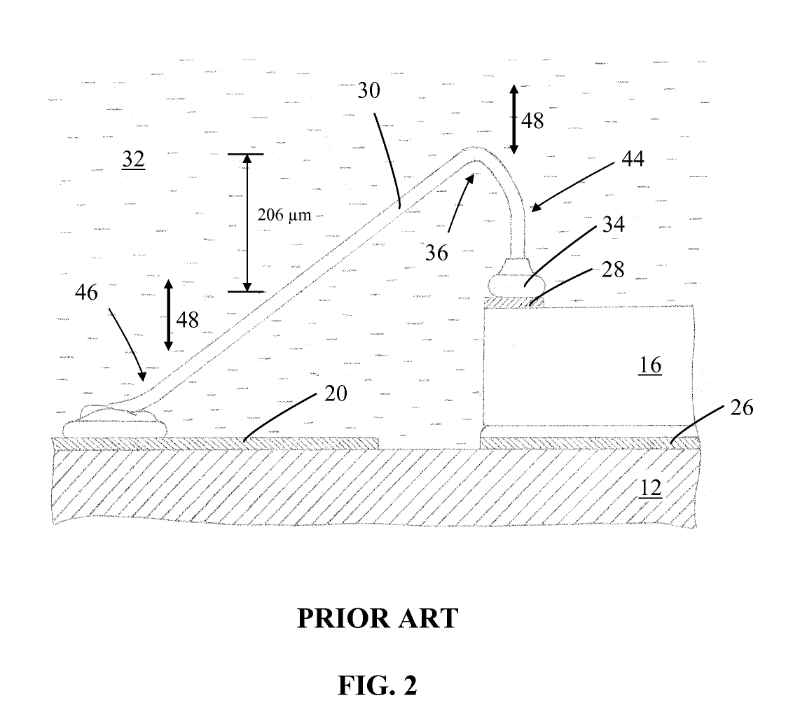

FIG. 2 is a schematic representation of a known bond wire 30 that is used to electrically connect the electrode contacts (anode, cathode) 28 of the LED die 16 to an electrical contact 20 of the package. Typically the bond wire 30 comprises a gold or gold alloy and has a spherical end enabling attachment of the bond wire to the electrode contact by ultrasonic welding. During the welding process the spherical end 34 becomes compressed and as shown is an oblate spheroid in form. The bond wire 30 curves 36 away from the electrode contact 28 towards the contact 20.

One test that LED-based light emitting devices are subjected to is Rapid Thermal Shock (RTS) testing in which the device is rapidly cycled between high T_{H} and low T_{L} set temperatures. For example the device can be heated to a high set temperature T_{H}=150° C. and maintained at this temperature for a set period of for example 30 minutes. The device is then rapidly (10 seconds) cooled to the low set temperature T_{L}=−45° C. and maintained at this temperature for the same set period (30 minutes). The process is repeated over many cycles to check for failure of the device. TABLE 1 gives the proportion (percentage) of devices that fail versus the number of temperature cycles for an LED-based light emitting device using the bond wire of FIG. 2. The RTS test are for set temperatures T_{H}=150° C. and T_{L}=−40° C. and a set time period of 5 minutes. As can be seen from the table just over 50% of the devices failed after 300 temperature cycles and 90% after 500 temperature cycles.

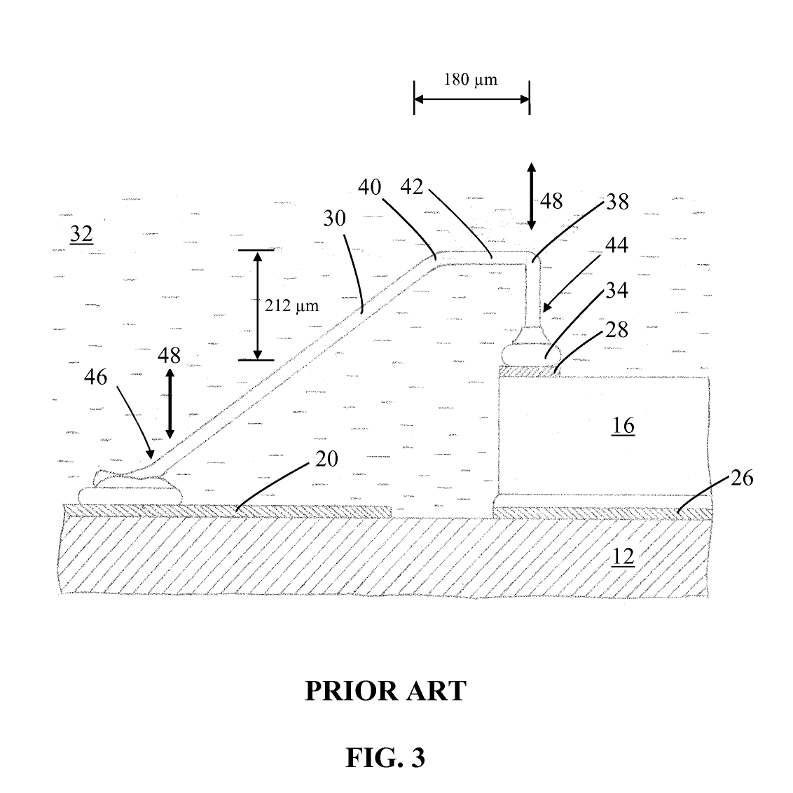

FIG. 3 is a schematic representation of another known bond wire arrangement 30 that is used to electrically connect the LED die 16 to the contact 20 of the package. In this arrangement the bond wire 30 includes two bends 38, 40 that are connected by a straight portion 42 in which the bend 38 nearest the LED die is a right angled elbow and the other 40 is approximately 45°. TABLE 1 also gives values for the percentage of devices that fail versus the number of temperature cycles for devices using the bond wire of FIG. 3. As can be seen from the table 100% of the devices failed after 200 temperature cycles.

The inventors have discovered that failure of the device results from a failure of the bond wire 30 in regions 44, 46 where the bond wire 30 is connected to the LED die and package contact 20. It is believed that failure of the bond wire results from the large difference in the coefficient of thermal expansion (CTE) of the bond wire 30, light transmissive encapsulation material 32 and package material. For example the bond wire is typically gold or a gold alloy and has a CTE<25 ppm whilst the package which can be a LTCC has a CTE<50 ppm. In contrast the light transmissive encapsulation material 34 which typically comprises a silicone or epoxy resin has a CTE>150 ppm. As a result of the differential differences in CTE the light transmissive encapsulation exerts a force (pulls) on the bond wire during thermal cycling resulting in fatigue and eventual failure of the bond wire. In FIGS. 2 and 3 arrows 48 indicate the general direction of the net force on the bond wire for a generally hemispherical encapsulation.

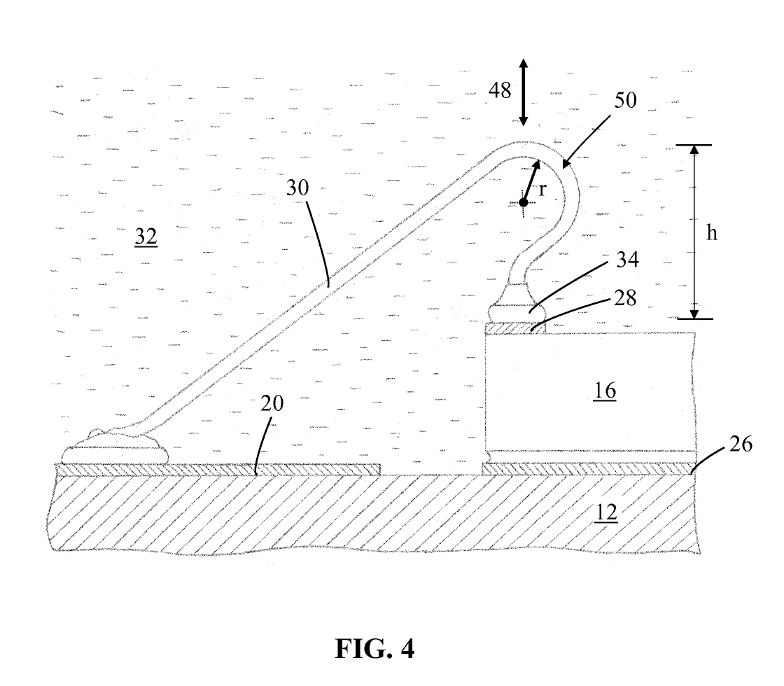

FIG. 4 is a schematic representation of an LED bond wire 30 in accordance with an embodiment of the invention. In accordance with the invention the bond wire 30 includes a semicircular hook-shaped (looped) end portion 50 that is configured such that the bond wire loops back on itself before connecting to the LED die. The shape of the bond wire 30 resembles a shepherd's hook (crook) or “candy cane”. The hook-shaped end portion 50 is resiliently deformable in the direction 48 allowing deformation (compression and expansion) of the bond wire and thereby reducing fatigue and potential failure of the bond wire during thermal cycling. As can be seen from TABLE 1 no devices incorporating the bond wire of the invention failed after 600 temperature cycles. After 700 temperature cycles 21% of devices failed and 50% after 800 cycles.

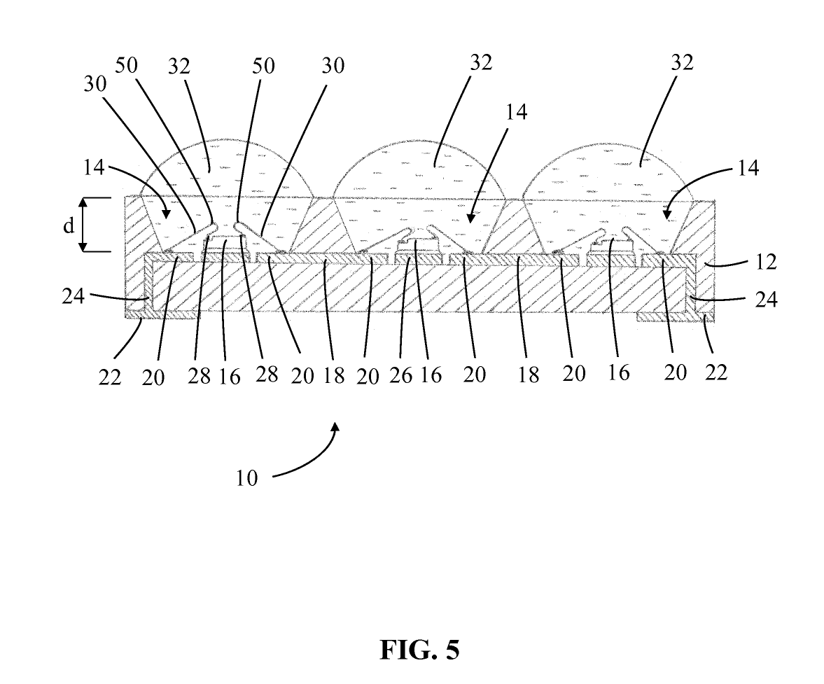

To maximize the magnitude of deformation that the bond wire can withstand the looped portion 50 is configured to have as large a radius r as practical and is largely determined by the physical constraints of the packaging arrangement. For example FIG. 5 is an LED-based light emitting device in accordance with an embodiment of the invention in which each cavity 14 is of a depth d≈0.5 mm whilst the LED die is of depth ≈0.15 mm leaving ≈0.35 mm between the top of the LED die and top surface of the package. To allow for possible shrinkage of the light transmissive material 32 and to ensure that the bond wire is fully encapsulated when the cavity is filled level, the height h of the loop above the surface of the LED die is typically selected to be h≈0.22 mm. This corresponds to a looped portion of radius r≈0.1 mm.

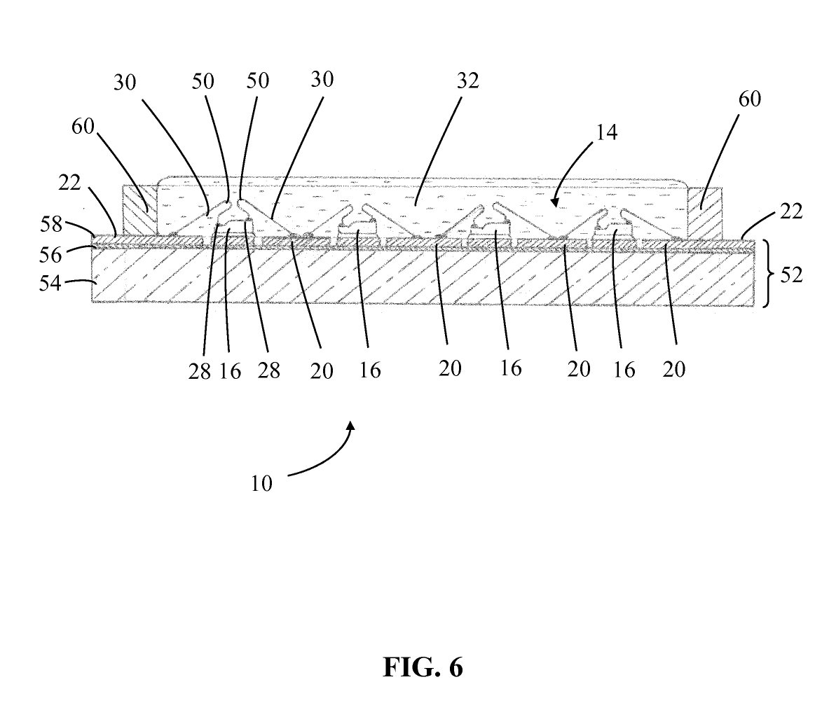

FIG. 6 is an LED-based light emitting device in accordance with an embodiment of the invention in which the LED dies 16 are mounted on a metal core printed circuit board (MCPCB) 52. As is known an MCPCB comprises a layered structure composed of a metal core base 54, typically aluminum, one or more thermally conducting/electrically insulating dielectric layers 56 and one or more copper circuit layers 58 for electrically connecting the LED dies 16 in a desired circuit configuration. A frame 60, for example a circular annular ceramic or metal frame, is mounted to the MCPCB 52 and is configured to surround the LED dies 16 and define a single shallow recess 14. The recess 14 can be filled with a light transmissive material 32, typically a silicone material, to fully encapsulate the LED dies 16 and bond wires 30.

It will be appreciated that LED-based light emitting devices in accordance with the invention are not limited to exemplary embodiments described and that variations can be made within the scope of the invention. For example whilst the bond wire has been described as being used to electrically connect the LED die to electrical contacts that are part of the package, the bond wires of the invention can also be used to interconnect LED dies.

TABLE 1

| Bond | Percentage (%) failure of wire bond after: | | | | | | | | | |
|---|---|---|---|---|---|---|---|---|---|---|
| wire | 20 | 40 | 60 | 80 | 100 | 200 | 300 | 400 | 500 | 600 |
| Shape | cycles | cycles | cycles | cycles | cycles | cycles | cycles | cycles | cycles | Cycles |
| FIG. 2 | 7 | 14 | 17 | 17 | 17 | 17 | 52 | 72 | 90 | — |
| FIG. 3 | 0 | 0 | 4 | 4 | 8 | 100 | — | — | — | — |
| FIG. 4 | 0 | 0 | 0 | 0 | 0 | 0 | 0 | 0 | 0 | 0 |

What is claimed is:

1. A light emitting device comprising:
a substrate;
at least one LED die mounted to the substrate;
at least one bond wire that electrically connects the LED die; and
a light transmissive material encapsulating the at least one LED die and at least one bond wire; wherein
the at least one bond wire has a hook-shaped portion that loops back on itself.

2. The device of claim 1, wherein the hook-shaped portion extends above the LED die by a distance of at least 0.2 mm.

3. The device of claim 1, wherein the hook-shaped portion is substantially semicircular in form.

4. The device of claim 2, wherein the hook-shaped portion has a radius of at least 0.1 mm.

5. The device of claim 1, wherein the at least one bond wire is “candy cane” in shape.

6. The device of claim 1, wherein the substrate comprises a package having a cavity in which the at least one LED die is mounted.

7. The device of claim 1, wherein the substrate comprises a metal core printed circuit board.

8. A light emitting device comprising: at least one LED die that is electrically connected by a bond wire having a hook-shaped portion that loops back on itself.

9. The device of claim 8, wherein the wherein the hook-shaped portion extends above the LED die by a distance of at least 0.2 mm.

10. The device of claim 8, wherein the hook-shaped portion is substantially semicircular in form.

11. The device of claim 10, wherein the hook-shaped portion has a radius of at least 0.1 mm.
